(19) United States
(12) Patent Application Publication
(10) Pub. No.: US 2008/0253438 A1
(43) Pub. Date: Oct. 16, 2008

(54) Near-Minimum Bit-Error Rate Equalizer Adaptation

(75) Inventors: Jamal Riani, Eindhoven (NL); Steven J-M., L. Van Beneden, Eindhoven (NL); Johannes Wilhelmus Maria Bergmans, Eindhoven (NL); Albert Hendrik Jan Immink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/093,963

(22) PCT Filed: Nov. 10, 2006
(86) PCT No.: PCT/IB06/54195

§ 371 Date: May 16, 2008

(30) Foreign Application Priority Data
Nov. 18, 2005 (EP) 05300939.5

(51) Int. Cl. H04L 25/03; H03K 5/159

(52) U.S. Cl. 375/232; 375/341

(57) ABSTRACT

Method for equalizer adaptation and/or target adaptation in a receiver for a transmission channel. The method provides for detecting data in the received signal, deriving an error sequence representing potential errors in the data detection, deriving a first value representing the likelihood of an error in the data detection, the first value based on the error sequence and the received signal, and enabling and disabling adaptation of the equalizer and/or the target response depending on the first value being below or above a predefined threshold value.

### TECHNICAL FIELD

The invention relates to a system and method for equalizer adaptation for data transmission channels, for the reduction of bit-error rates.

### BACKGROUND OF THE INVENTION

In data transmission channels used in data storage systems, and wired and wireless communication systems, digital data may be transferred via a dispersive channel in the presence of noise. This noise may be simple additive white Gaussian noise, but may also include data-dependent noise or correlated noise, such as intersymbol interference. On the receiver end of the system the transmitted digital data is detected based on a sampled analog and noisy received signal. A bit detector in the receiver analyses the received signal and “estimates” the sequence of bits or symbols of the transmitted data. The optimal receiver for estimating a data sequence in the presence of intersymbol interference and additive white Gaussian noise can generally not be realized because of its excessive complexity, and this has led to development of a variety of suboptimal receivers.

A bit detector on the receiving end of the channel typically uses some error criterion to minimize error in bit-detection of the received or replay signal. One such criterion is the minimization of the Euclidian distance between the received signal r and the expected or reference signal, assuming some transmitted bit sequence b. The reference signal may be calculated based on a mathematical model of the desired channel, the so-called target response g of the channel. The Euclidian distance between the received and the reference signal can be written mathematically as:

$$E = {\sum }_{- ∞}^{∞} {[ {r}_{k} - {( b * g )}_{k} ]}^{2} \qquad Eq . ( 1 )$$

where * represents the convolution operation. A conventional technique to modify a received signal r to resemble the expected signal as nearly as possible is by linear equalization of the received signal. The received signal is filtered by a linear equalizer with a finite impulse response filter. The taps of the filter are adapted in such a way that an error criterion is minimized.

FIG. 1 shows a schematic block diagram of a conventional partial response maximum likelihood (PRML) system. A binary sequence bₖ is transmitted, at a rate 1/T, over a transmission channel 12. Channel 12 is a linear or nonlinear dispersive channel with finite impulse response hₖ and may be, for example, a wired or wireless communication channel or a replay channel of an optical or magnetic disk storage system or the like. The channel output is corrupted by the addition of noise nₖ. The received or replay signal rₖ is the sampled analog noisy channel output and is given by:

rₖ=(h*b)ₖ+nₖ Eq (2)

The received signal rₖ is input to equalizer 14. The channel impulse response hₖ is typically quite long and may be time-varying. For the equalizer 14, an adaptive partial response equalizer may be used to transform the channel response to a shorter and more well defined impulse response. The equalizer 14 impulse response wₖ is optimized adaptively so that the overall impulse response, from the channel input to the equalizer output, is as close as possible to a prescribed short impulse response, referred to as the target response gₖ. The target response gₖ is a mathematical model of the desired channel, and has length N_{g}. The equalizer output xₖ serves as input to the Viterbi detector 16 that produces bit decisions \hat{b}ₖ. The Viterbi detector trellis is matched to the target response and has Nₛ states. For uncoded binary data, Nₛ=2^{Ng-1}.

A linear filter or look-up table 18 is used to generate a reference or expected signal. In the data-aided mode, used to tune the receiver and settle the system, the input to the filter 18 is the transmitted binary sequence bₖ. In the decision-directed mode, used for operation, the input to the filter 18 is the output of the Viterbi detector \hat{b}ₖ. The reference signal (g*b)ₖ output from the filter 18 serves as a second input to the Viterbi detector 16.

The reference signal is also used to compute the error signal at the Viterbi detector input εₖ. This error signal contains contributions of the channel noise and residual inter-symbol interference caused by mis-equalization, i.e. due to the mismatch between the desired response at the detector input, i.e. gₖ, and the actual response, i.e. w*hₖ. The Viterbi detector input xₖ is ideally equal to the reference signal, but with the addition of channel noise and residual ISI, the input xₖ can be expressed as:

xₖ=(g*b)ₖ+δₖ Eq (3)

In conventional systems the coefficients of equalizer 14 are tuned adaptively based on the error signal εₖ. Both the equalizer and the target can be adapted to obtain the optimum noise spectral density and optimum target in order to minimize bit-error rate. Examples of conventional adaptation algorithms are the zero-forcing method or the least mean square algorithm. However, these algorithms are designed to minimize the error signal (for example in the mean square sense) regardless of any error signal correlation or data-dependency, as caused for example by residual inter symbol interference (ISI) due to mis-equalization. These methods do not minimize the bit-error rate directly and tend to achieve a bit-error rate that is far from optimum under worst-case conditions.

It is an object of the invention to provide a system and method that takes into account error signal correlation and data-dependency and that seeks to drive the overall bit-error rate to its optimal value.

### SUMMARY OF THE INVENTION

A solution to the above problems is found in a method that extracts error-likelihood information from the data detector, where the error-likelihood information is based on the possible error sequence and the incoming data signal. The invention provides a method for equalizer and/or target adaptation in a receiver for a transmission channel, a transmitted data sequence being input to the transmission channel and a received data signal being output from the transmission channel. The method provides for detecting data in the received signal, deriving an error sequence representing potential decision errors in the data detection, deriving a first value representing the likelihood of a decision error in the data detection, the first value based on the error sequence and the received signal, and enabling and disabling adaptation of the equalizer and/or the target response depending on the first value being below or above a predefined threshold value.

The first value is preferably derived from the difference in path metric between the best path and the second best path in a Viterbi detector included in the receiver. The threshold value is preferably derived from the error sequence, and may be proportional to the Euclidian weight of the error sequence. Alternatively, the first value may be derived from the difference of the squared distances between, on the one hand, the detector input and its closest symbol found by a symbol-by-symbol detector and, on the other hand, the detector input and its second closest symbol.

The adaptation of the equalizer and/or the target response preferably comprises correlating the received signal with a second value derived from the error sequence, and the second value is preferably derived from the error sequence and the expected target response for the transmission channel. The adaptation of the equalizer and/or the target response may alternatively comprise correlating the received signal with the error sequence. In addition, the adaptation of the equalizer and/or the target response preferably includes scaling by an adaptation constant dependent on the error sequence, and the adaptation constant is preferably dependent on the Hamming weight of the error sequence.

The invention also provides for a receiver for a transmission channel comprising a linear equalizer receiving the data signal and generating a reference signal, an adaptation means for adjusting the equalizer, and a data detector for receiving the reference signal and detecting data in the received signal. The detector derives a first value representing the likelihood of a decision error in the data detection, the first value based on the received signal and an error sequence representing potential decision errors in the data detection. A switch is provided for enabling the adaptation circuit in dependence on the first value being below or above a predefined threshold value.

The detector is preferably a Viterbi detector, and first value is preferably derived from the difference in total path metric between the best path and the second best path in the Viterbi detector, and the threshold value is preferably derived from the error sequence, and may be proportional to the Euclidian weight of the error sequence eₖ. Alternatively, the detector may be a symbol-by-symbol detector, and the first value derived from the difference of the squared distances between the detector input and its closest symbol found by a symbol-by-symbol detector, and the detector input and its second closest symbol.

The receiver may include a target response for generating a reference signal, an adaptation means for adjusting the target response, and means for enabling the adaptation means in dependence on the first value being below or above a predefined threshold value. The adaptation means preferably includes means for correlating the signal in the adaptation signal with the error sequence or with a second value derived from the error sequence, where the second value is preferably derived from the error sequence and the expected target response for the transmission channel. The adaptation means may also include means for scaling by an adaptation constant dependent on the error sequence, which may be dependent on the Hamming weight of the error sequence.

### BRIEF DESCRIPTION OF THE DRAWINGS

Further aspects, features and advantages of various embodiments of the invention will become apparent from the following description, given by way of example only, of preferred embodiments of the invention, referring to the accompanying drawings, wherein:

FIG. 1 is a schematic block diagram of a conventional partial response maximum likelihood system.

FIG. 2 is a conceptual diagram of a Viterbi detector.

FIG. 3 is a block diagram of a first embodiment of the invention implemented in a partial response maximum likelihood system.

FIG. 4 is a block diagram of a second simplified embodiment of the invention.

FIG. 5 is a block diagram of a third embodiment of the invention in a system utilizing a symbol-by-symbol detector.

FIG. 6 is a block diagram of a fourth embodiment of the invention implemented in a equalized maximum likelihood system.

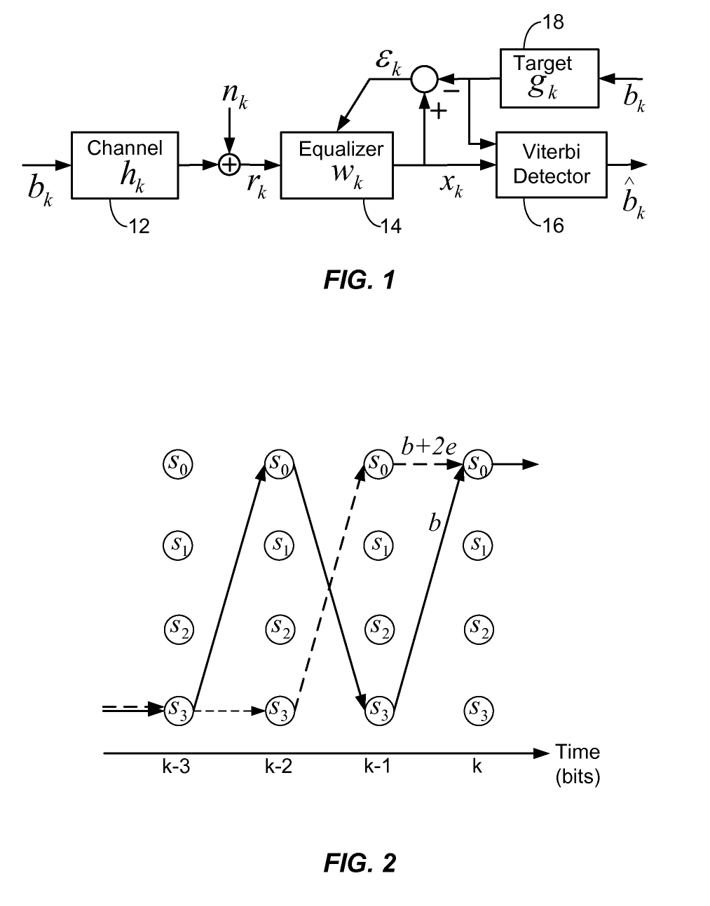

### DESCRIPTION OF PREFERRED EMBODIMENTS

In one embodiment of the invention, error-likelihood information is derived from a Viterbi detector in a partial response maximum likelihood (PRML) system or equalized maximum likelihood (EML) system. FIG. 2 shows a conceptual diagram of a Viterbi detector. The Viterbi detector in FIG. 2 operates on a trellis that is matched to the target response gₖ. Each path in this trellis corresponds to an admissible bit sequence, and the detector selects the sequence that leads to the smallest path metric in the trellis. The metric of a bit sequence bₖ is given by the Euclidian metric:

$$M ( b ) = {\sum }_{k} {[ {x}_{k} - {( g * b )}_{k} ]}^{2} \qquad Eq . ( 4 )$$

where the above summation is taken over all received symbols indices. The Viterbi detector of FIG. 2 has a 4-state trellis, although actual implementations may have a different number of states. At time kT, the Viterbi detector employs, for every state, an Add Compare Select (ACS) operation to select the best path arriving at each state; the second best path is discarded. For example, if the path corresponding to the transmitted bit sequence bₖ arrives at state S₀ at time kT, we can denote by b⁰ₖ and b¹ₖ the selected and discarded paths by the ACS operation at state S₀ and time kT.

An erroneous ACS decision will occur at time kT when the correct path, corresponding to bₖ, is discarded, i.e. when b¹=b. The (erroneously) selected path in this case is b⁰=b+2e, where e=½ (b⁰−b) is referred to as the bit-error sequence. This erroneous ACS decision occurs with a probability:

Pr(ACS error|b,e)=Pr(M(b+2e)−M(b)<0) Eq. (5)

Equation (5) above represents the probability that the ACS operation of the Viterbi detector induces a decision error, by discarding the correct path, given the transmitted bit sequence bₖ and an admissible bit-error sequence eₖ. The overall bit-error rate of the Viterbi detector is directly related to the probability of ACS decision errors over all possible data patterns and admissible bit-error sequences. In practice, system performance is determined by a limited set of dominant bit-error sequences that span few bits, e.g. single bit errors and specific double bit errors. In terms of paths in the Viterbi detector trellis, this means that the correct path and the erroneously detected path would differ only for a few bits and then merge again. The detection error in the Viterbi detector is thus caused by an ACS error at the state where these paths merge. Thus, minimizing the probability of ACS error for a given bit-error sequence leads to optimization of bit-error rate for that specific bit-error sequence in the overall bit-error rate.

### Equalizer Adaptation

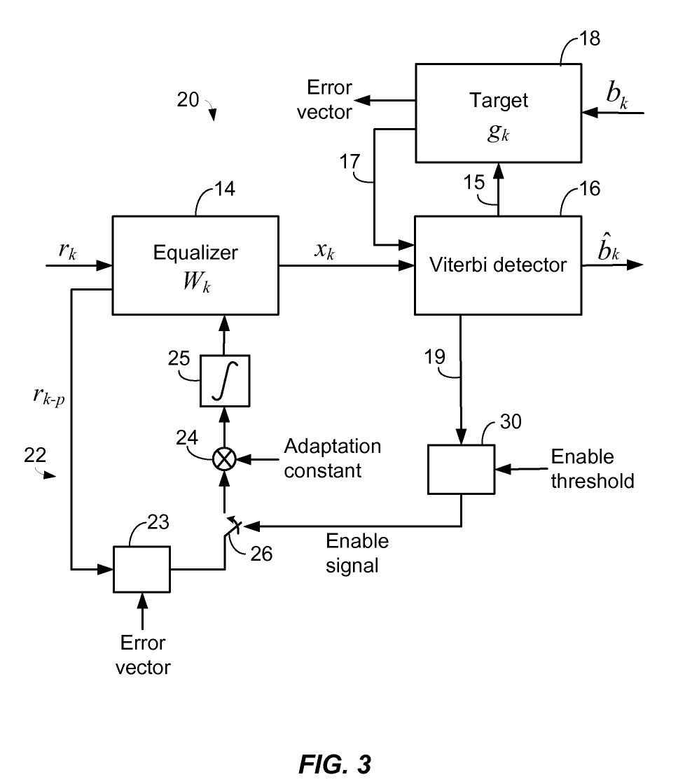

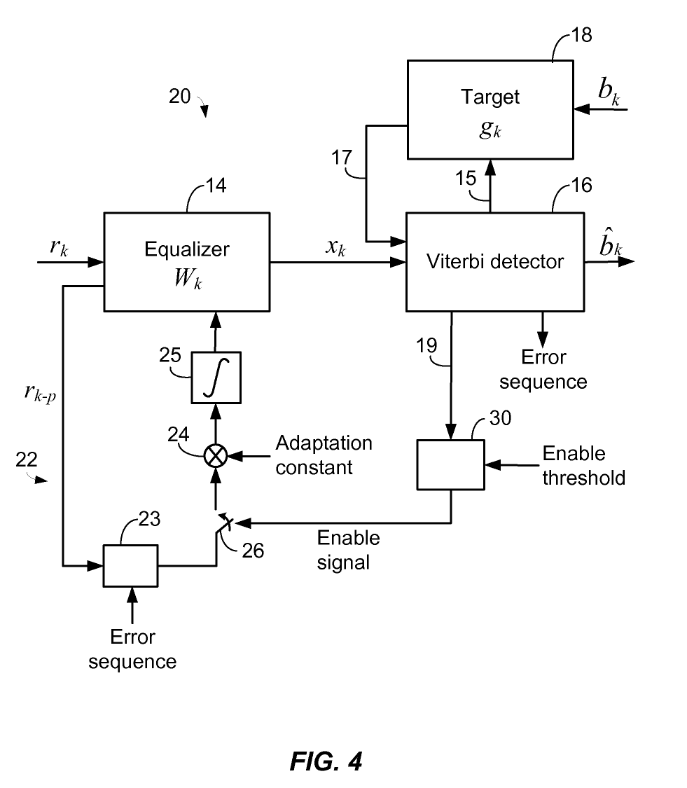

The embodiment of FIG. 3 makes use of a parameter called the sequenced amplitude margin (SAM) value in a partial response maximum likelihood (PRML) system. In this system, bit detection is performed by selecting the data sequence \hat{b} that results in the smallest Euclidian metric, as defined in Eq. (4). If the correct data sequence is selected by the Viterbi detector (i.e. b=\hat{b}), then its Euclidian metric will be determined solely by the noise in the received signal:

$$M ( b ) = {\sum }_{- ∞}^{∞} {[ {( b * g )}_{k} + {ɛ}_{k} - {( b * g )}_{k} ]}^{2} = {\sum }_{- ∞}^{∞} {ɛ}_{k}^{2} \qquad Eq . ( 6 )$$

If one or more bit errors are made according to the bit-error sequence e=½(b⁰−b), where b⁰=b+2e is the erroneously detected bit-sequence, the Euclidian metric of the detected bit sequence then becomes:

$$\begin{matrix}M ( b + 2 e ) = {\sum }_{- ∞}^{∞} {[ {( b * g )}_{k} + {ɛ}_{k} - {( ( b + 2 e ) * g )}_{k} ]}^{2} \\ = {\sum }_{- ∞}^{∞} {[ {ɛ}_{k} - 2 {( e * g )}_{k} ]}^{2}\end{matrix} \qquad Eq . ( 7 )$$

A decision error will occur when the desired signal for the erroneously detected sequence gives a better match to the actually received signal than the desired signal for the transmitted data, i.e. when

M(b+2e)≦M(b) Eq. (8)

Using equations (6) and (7) in equation (8) yields the expression:

$${\sum }_{- ∞}^{∞} {[ {ɛ}_{k} - 2 {( e * g )}_{k} ]}^{2} \leq {\sum }_{- ∞}^{∞} {ɛ}_{k}^{2} \qquad Eq . ( 9 )$$

This can be rewritten as:

$${\sum }_{- ∞}^{∞} {( e * g )}_{k}^{2} + {\sum }_{–∞}^{∞} {{ɛ}_{k} ( e * g )}_{k} \leq 0 \qquad Eq . ( 10 )$$

The first term relates to the signal energy resulting from the transmission of a bit-error sequence e through the channel, often referred to as the Euclidian weight of the particular bit-error sequence, i.e

$${\sum }_{- ∞}^{∞} {( e * g )}_{k}^{2} .$$

The second term is linearly dependent on εₖ. The value on the left part of equation (10) is generally denoted the sequenced amplitude margin (SAM) value:

$$SAM = {\sum }_{- ∞}^{∞} {( e * g )}_{k}^{2} + {\sum }_{- ∞}^{∞} {{ɛ}_{k} ( e * g )}_{k} \qquad Eq . ( 11 )$$

If the SAM value is negative, this indicates that a decision error has been made by the Viterbi detector. A single SAM value is associated with each admissible bit-error sequence. The SAM value gives a direct indication of the probability that the receiver has made a decision error. If the SAM value is below a certain value the receiver can be said to be in danger of making a decision error and the taps of the equalizer may be adjusted so that in a future similar situation (i.e. a situation with the same data and data-dependent noise realization) the SAM value is larger. This is the basic operating mechanism of the invention.

A block diagram of one implementation of the invention is shown in FIG. 3. The received (noisy) signal rₖ from a transmission channel 12 (not shown) is an input to linear equalizer 14. The equalizer output xₖ is an input to Viterbi detector 16, and the Viterbi detector output is the detected bit sequence \hat{b}ₖ. The target channel response model 18, for example implemented as a filter or look-up table. In the data-aided mode, target 18 receives the transmitted bit-sequence bₖ, and in the decision-directed mode, target 18 receives a local bit-sequence estimate signal 15 from the Viterbi detector. Target 18 generates the reference signal 17 as described previously, and also generates an error vector δₑ described below.

An equalizer adaptation loop 22 includes vector correlator multiplier 23, scalar multiplier 24, and discrete-time integrator 25. The adaptation loop includes an enable switch or device 26 which enables or disables the adaptation loop 22 in dependence on an enabling signal.

In FIG. 3 the received signal rₖ₋ₚ is shown as input to the adaptation loop for adaptation of the p^{th} equalizer tap value of equalizer 14. At every clock cycle kT, an ACS operation is employed at every state in the Viterbi detector 16. At the decoding state, i.e. the state used for backtracking in the Viterbi detector trellis, two quantities are derived from the add-compare-select (ACS) module in the Viterbi detector. First, the difference in path metrics between the selected (best) and the second best paths is derived. Second, a bit-error sequence eₖ is derived as the bitwise difference between the two sequences corresponding to the selected and second best paths. The Viterbi detector 16 will require a register to store the sequences corresponding to the selected and second best paths (note that the second best path is discarded in the conventional system described above), and circuitry to calculate the bitwise difference between these two sequences.

The difference in total path metric between the best path (the path that is actually chosen) and the second best path is a calculation of the SAM value. The best path is ideally represented in equation (6) above, showing the Euclidian metric for bit sequence b, i.e. M(b), and the second best path in equation (7) above, showing the Euclidian metric for bit sequence b+2e, i.e. M(b+2e). However, the SAM value 19 calculated by the Viterbi detector 16 is limited by the back-tracking depth of the detector and the memory of the channel 12. The SAM value 19 is compared with a predefined threshold resulting in an enable signal for the adaptation loop 22.

The bit-error sequence eₖ from the Viterbi detector is used to compute an error vector δₑ, which can be calculated as [(g*e)ₖ, (g*e)ₖ₋₁, . . . (g*e)_{k-N}]^{T}, where g is the target response and the integer value N depends on the maximum length of relevant bit-error sequences. N may be simply fixed to the backtracking depth of the Viterbi detector.

The adaptation loop 22 adds a correlation between the received signal and the error vector to the taps of the linear equalizer 14. The equalizer adaptation is enabled only when the difference in path metrics is smaller than a threshold value proportional to the Euclidean weight of the bit-error sequence eₖ. The threshold may be calculated as Tₕ=4αδₑ^{T}δₑ, where α is a proportionality factor. A satisfactory choice for α has been found to be ½.

When the adaptation is enabled, the scalar product of the error vector δₑ with the equalizer input vector rₖ is calculated by vector multiplier (correlator) 23 for each tap of the equalizer, the input vector for the p^{th} equalizer tap rₖ₋ₚ=[rₖ₋ₚ, rₖ₋ₚ₋₁, . . . r_{k-p-N}]^{T}. The resulting scalar product is scaled with the adaptation constant −η(e) by the scalar multiplier 24, and then passed to an ideal discrete-time integrator 25 to generate the updated tap value of each equalizer tap of equalizer 14. The adaptation constant, which determines the bandwidth of the adaptation loop, may be dependent on the bit-error sequence to further improve the performance. The optimal adaptation constant is proportional to H_{w}(e) and can be expressed as η(e)=H_{w}(e) η₀, where H_{w}(e) is the Hamming weight of the bit-error sequence e, i.e. the number of non-zeros in e, and η₀ is a constant independent of the bit-error sequence eₖ. The constant η₀ determines the bandwidth of adaptation loop and the ability of the equalizer to follow fast variations in the received signal, and can be determined using considerations well known to those of skill in the art.

Note that in the decision-directed mode, where the transmitted bits are not available at the receiver side, the SAM value, taken as the difference between the best and the second best paths in the Viterbi trellis, is always positive. In this case the best path in the Viterbi trellis is assumed to be the correct one and the second best path serves to compute the bit-error sequence. The remaining part of the equalizer adaptation circuit is unchanged.

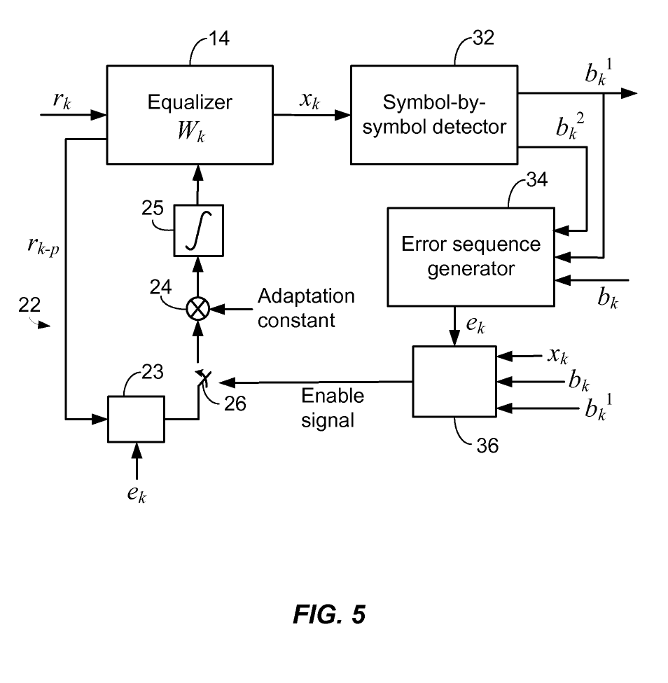

FIG. 5 is a block diagram of a third embodiment implemented in a partial response maximum likelihood system utilizing a symbol-by-symbol detector in place of a Viterbi detector. The use of a symbol-by-symbol detector in the receiver permits the equalizer adaptation to be simplified. In this embodiment, the receiver comprises of a linear equalizer 14, multilevel threshold (symbol-by-symbol) detector 32, error sequence generator 34, enable signal generator 36, and adaptation loop 22 (described for the previous embodiments). The equalizer output xₖ is input to detector 32. Similarly to the Viterbi detector of the previous embodiments, the detector 32 is modified to output not only the closest symbol to xₖ but also the second closest symbol. These outputs are denoted bₖ¹ for the closest symbol to xₖ and bₖ² for the second closest symbol to xₖ.

Error sequence generator 34 produces at every clock cycle a possible error sequence. For symbol-by-symbol detection, preferably only single symbol errors are considered. The derivation of the symbol error sequence eₖ differs in the data-aided and decision-directed modes. In the data-aided mode, the transmitted symbols bₖ are known and the error sequence can be calculated as 2eₖ=b¹ₖ−bₖ if b¹ₖ≠bₖ (i.e. in the case of a detection error) and 2eₖ=b²ₖ−b¹ₖ if b¹ₖ=bₖ. (i.e. in the case of no detection error). In the decision-directed mode, the detector 32 is assumed to output correct decisions and eₖ may be calculated simply as 2eₖ=b²ₖ−b¹ₖ. The Euclidian metric of the symbol sequence bₖ is given by M(b)=(xₖ−bₖ)². Similarly to the SAM value of the previous embodiments, the value (xₖ−b²ₖ)²−(xₖ−b¹ₖ)² represents the likelihood that the receiver is in danger of making a decision error in the decision-directed mode.

The enable signal generator 36 is also simpler than in the case of Viterbi detection. Given the (eventual) symbol error eₖ, the general expression of the enabling condition is given by M(b+2e)−M(b)<Tₕ in the data-aided mode and M(b¹+2e)−M(b¹)<Tₕ in the decision-directed mode (this latter expression is equivalent to the value (xₖ−b²ₖ)²−(xₖ−b¹ₖ)² and represents the likelihood of a decision error). Using the relations M(b)=(xₖ−bₖ)² and Tₕ=4αeₖ², the enabling condition can be expressed as (1−α)|eₖ|≦sign(eₖ)(xₖ−bₖ) in the data-aided mode and (1−α)|eₖ|≦sign(eₖ)(xₖ−b¹ₖ) in the decision-directed mode, where sign(x)=1 if x>0 and sign(x)=−1 otherwise. A satisfactory choice of a is ½.

The correlation of the equalizer input signal rₖ₋ₚ with the symbol error sequence eₖ is performed by correlator 23. The correlation is simplified in this case to eₖrₖ₋ₚ for the adaptation of the p^{th} tap of the equalizer 14. A further simplified version may be implemented requiring no multiplication, by using the correlation sign(eₖ)rₖ₋ₚ instead of eₖrₖ₋ₚ.

Intuitively the equalizer adaptation algorithm can be understood as follows. The error signal ε is projected onto a signature of a possible bit-error sequence (i.e., the signal that is received when the particular bit-error sequence would be transmitted across the channel). If this projection is above a certain threshold the bit-error sequence looks very much like the error signal that would be expected for the particular bit-error sequence. In that case the equalizer adaptation should be enabled because it is likely that the bit-detector will produce a decision error. In case adaptation is enabled the projection of the received signal itself on the error signature is subtracted from the equalizer taps. This means the next time this received signal occurs the projection of the relative change in equalizer output compared to the previous occurrence onto the error signature has decreased. This lowers the probability of the bit-detector making a decision error.

### Target Response Adaptation

The Viterbi detector in an EML system operates on a trellis that is matched to the linear target response g^{k}. For a given bit sequence bₖ and an admissible bit-error sequence eₖ, the cost function Δₑ may be defined as:

$$\begin{matrix}{Δ}_{e} = \frac{E [ {X}_{e}^{′} ]}{{T}_{e}} \\ where {X}_{e}^{′} = {X}_{e} {\prod }_{\{ Xe \geq Te \}} \{ \begin{matrix}{X}_{e} = {\underline{δ}}_{e}^{T} \underline{ɛ} & if {\underline{δ}}_{e}^{T} \underline{ɛ} > {T}_{e} \\ 0 & otherwise\end{matrix} \\ and {T}_{e} = ( 1 - α ) {\underline{δ}}_{e}^{T} {\underline{δ}}_{e} + {αμ}_{e} \\ and {μ}_{e} = E [ {\underline{δ}}_{e}^{T} \underline{ɛ} ] and α is a fixed value in the interval [ 0 , 1 ] .\end{matrix} \qquad Eq . ( 12 )$$

The near minimum bit error rate adaptation seeks to minimize the cost function Δₑ for all relevant bit-error sequences.

The cost function Δₑ involves the variable Xₑ=δₑ^{T}ε=Σₖ(g*e)ₖεₖ. The difference in path metrics between the sequences bₖ and bₖ+2eₖ depends on the error signal only via Xₑ. The denominator of Δₑ relates to the Euclidian weight of the bit-error sequence eₖ, i.e. δₑ^{T}δₑ. Optimization of the target response based on Δₑ will tend to decrease error signal coloration in the direction of δₑ and increase the Euclidian weight of the bit-error sequence eₖ. The threshold Tₑ above expresses the focusing of adaptation on bit sequences, bit-error sequences and noise realizations that correspond to the less reliable decision in the Viterbi Detector. In terms of path metrics in the Viterbi Detector, the enabling condition {Xₑ>Tₑ} can be expressed as {M(b+2e)−M(b)<4(δₑ^{T}δₑ−Tₑ)}, where M(b)=Σₖ(xₖ−(g*b)ₖ)² denotes the path metric of the sequence bₖ. The thresholding automatically selects the set of worst bit sequences and bit-error sequence which are decisive for BER. For example, considering mis-equalization ISI, the thresholding is equivalent to focusing the adaptation effort only on bit sequences and bit-error sequences fr which ISI is destructive, i.e. leading to degradation of predetection SNR.

The dependence of Tₑ on μₑ can be neglected because μₑ is much smaller than δₑ^{T}δₑ and, omitting the constant factor (1−α), the cost function Δₑ can be rewritten

$${Δ}_{e} = \frac{E [ {X}_{e}^{′} ]}{{\underline{δ}}_{e}^{T} {\underline{δ}}_{e}} \qquad Eq . ( 13 )$$

The enabling condition can be simplified as {M(b+2e)−M(b)<Tₕ, where the threshold Tₕ=4αδₑ^{T}δₑ, as described earlier.

In order to minimize the overall BER, the different functions Δₑ for the different bit-error sequences are combined with different weights for different bit-error sequences. The weight for a bit-error sequence eₖ is proportional to its Hamming weight H_{w}(e), i.e. the number of zeros in eₖ. For a given bit-error sequence eₖ the target adaptation scheme that minimizes Eq. (13) can be based on the steepest descent algorithm. This consists of following at each iteration the opposite direction of the gradient of Δₑ with respect to the target coefficients. The adaptation of the p^{th} target tap can be written as follows:

$${g}_{p}^{( k + 1 )} = {g}_{p}^{( k )} - {η}^{′} ( e ) \frac{\partial {Δ}_{e}}{\partial {g}_{p}} {\vert}_{g = {g}^{( k )}} \qquad Eq . ( 14 )$$

where gₚ^{(k)} is the p^{th} target tap at time kT. The coefficient η′(e) denotes the target adaptation constant and is ideally proportional to the Hamming weight of the bit-error sequence eₖ, i.e. η′(e)=η₀H_{w}(e) where η₀ is a positive constant value.

Upon replacing the expectation of X′ₑ in equation (13) by its instantaneous realization and taking its gradient with respect to the p^{th} target tap, an expression of the adaptation rule of equation (14) can be derived. This can be written as

$${g}_{p}^{( k + 1 )} = {g}_{p}^{( k )} - η ( e ) {Γ}_{p}^{( k )} {\prod }_{\{ \frac{{\underline{δ}}_{e}^{T} \underline{ɛ}}{{\underline{δ}}_{e}^{T} {\underline{δ}}_{e}} > ( 1 - α ) \}} \qquad ( Eq . 14 )$$

$${Γ}_{p}^{( k )} = \{ {\underline{e}}_{k - p}^{T} \underline{ɛ} - {\underline{δ}}_{e}^{T} {\underline{b}}_{k - p} - 2 \frac{{\underline{δ}}_{e}^{T} \underline{ɛ}}{{\underline{δ}}_{e}^{T} {\underline{δ}}_{e}} {\underline{δ}}_{e}^{T} {\underline{e}}_{k - p} \} \qquad Eq . ( 15 )$$

where

$$η ( e ) = {η}_{0} \frac{{H}_{w} ( e )}{{\underline{δ}}_{e}^{T} {\underline{δ}}_{e}} ,$$

bₖ₋ₚ=[bₖ₋ₚ, bₖ₋ₚ₋₁, . . . ], eₖ₋ₚ=[eₖ₋ₚ, eₖ₋ₚ₋₁, . . . ] and εₖ₋ₚ=[εₖ₋ₚ, εₖ₋ₚ₋₁, . . . ]. The term

$$\frac{{\underline{δ}}_{e}^{T} \underline{ɛ}}{{\underline{δ}}_{e}^{T} {\underline{δ}}_{e}}$$

on the right hand expression of Eq. (15) can be interpreted as a weighing factor in the maximization of the Euclidian distance δₑ^{T}δₑ with respect to the minimization of δₑ^{T}ε. To simplify equation (15), this term can be simply fixed to a value β that meets the enabling condition, i.e. β>1−α. A simple choice of β is β=1. Moreover, depending on the dominant bit-error sequences, the ratio

$$\frac{{H}_{w} ( e )}{{\underline{δ}}_{e}^{T} {\underline{δ}}_{e}}$$

in the expression of the adaptation constant η(e) can be assumed to be approximately independent of eₖ. This would further simplify equation (14).

Using these approximations and expressing the enabling condition in terms of the Viterbi detector path metrics, equations (14) and (15) can be rewritten as

gₚ^{(k+1)}=gₚ^{(k)}−η(e)Γₚ^{(k)}Π_{{M(b+2e)-M(b)<4α}δₑ^{T}δ_{e}} Eq. (16)

Γₚ^{(k)}=eₖ₋ₚ^{T}ε−δₑ^{T}(bₖ₋ₚ+2eₖ₋ₚ). Eq. (17)

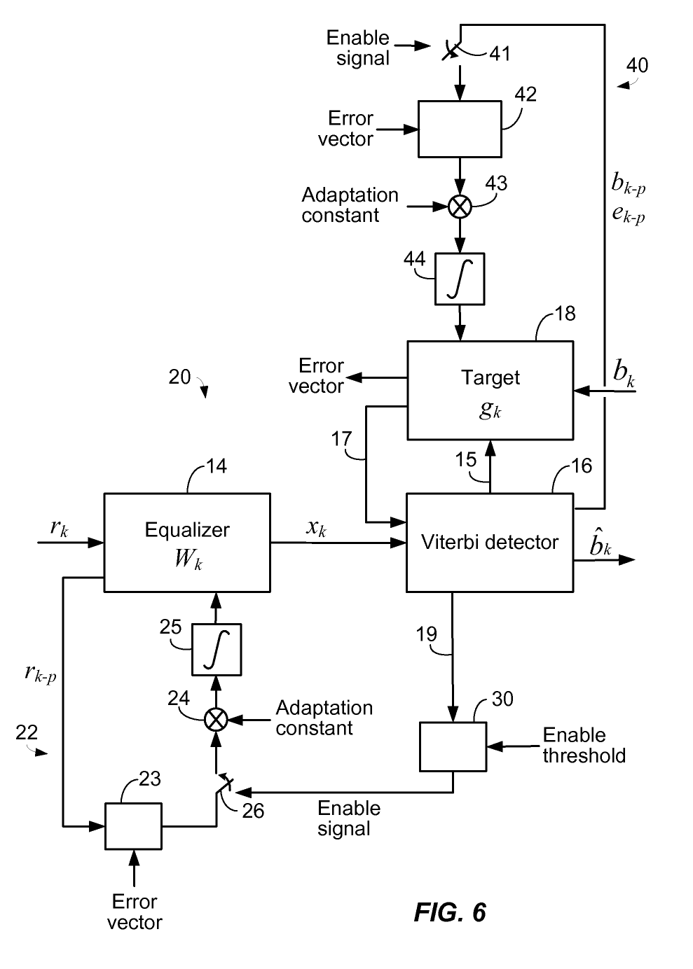

FIG. 6 shows an embodiment of the invention implementing target adaptation and equalizer adaptation in an equalized maximum likelihood system. A target adaptation loop 40 includes an enable switch or device 41 which enables or disables the target adaptation loop 40 in dependence on an enabling signal. The target adaptation loop 40 also includes vector correlator multiplier 42, scalar multiplier 43, and discrete-time integrator 44.

The overall target adaptation is performed as follows. At every clock cycle kT, an ACS operation is employed in the Viterbi detector 16 at every state. At the decoding state, two quantities are derived. First, the difference in path metrics between the selected and the discarded paths is taken. Second, a bit-error sequence eₖ is derived as the bitwise difference between the two sequences corresponding to the discarded and the selected paths. This derivation of the bit-error sequence reflects the Decision Directed (DD) mode where the transmitted data is not known to the receiver. In the Data Aided (DA) mode where the transmitted data is available to the receiver as a known preamble, the derivation of the bit-error sequence is simpler because the state that corresponds to the transmitted data is known at every clock cycle. In this case, the bit-error sequence corresponds to the discarded path by the ACS operation if the ACS decision is correct and to the selected path otherwise.

The bit-error sequence eₖ is used to compute the error vector δₑ=[(g*e)ₖ, (g*e)ₖ₋₁, . . . (g*e)k−N]^{T}, where the integer value N depends on the maximum length of relevant bit-error sequences. The value N can be fixed to the backtracking depth of the Viterbi detector. The target adaptation is enabled when the difference in path metrics is smaller than a threshold value proportional to the Euclidian weight of the bit-error sequence. The threshold may be calculated as Tₕ=4αδₑ^{T}δₑ as discussed in relation to the equalizer adaptation. When the enable signal is set to enable target adaptation, the expression Γₚ^{(k)} in equation (17) is evaluated by vector correlator multiplier 42, scaled by adaptation constant −η(e) in scalar multiplier 43, and then passed to the discrete-time integrator 44 that produces the updated p^{th} target tap value. It should be noted that the evaluation of Γₚ^{(k)} does not require real multiplications.

Digital recording systems often employ parity-check (PC) and error correction codes (ECC) in order to tackle the remaining bit-errors at the Viterbi Detector output. The performance of these codes depends on the dominant bit-error sequences after the Viterbi Detector. Therefore, to optimize sector error rate after PC and ECC decoding, the adaptation constants η(e) can be better chosen such that the target and equalizer adaptation focuses primarily on the error sequences that are not covered or ‘less covered’ by the PC and ECC. In other words, the invention can be generalized to achieve sector error rate minimization through optimization of the adaptation constants η(e).

### Interaction Between Equalizer and Target Adaptation

The bit error rate of the EML system of FIG. 6 does not change if the equalizer and target responses are scaled with the same factor. This interaction can cause the equalizer and target energy to drift to big values or decrease to very small values which may lead to saturation or quantization problems in fixed-point implementations. This interaction can be addressed in a variety of ways. One approach is to fix the energy of the target response. The target adaptation rule of equation (17) can be modified so that after every adaptation the target is scaled to have a unit energy.

Another interaction effect may arise from the fact that, for a linear channel and long equalizer 14, bit error rate is independent of the phrase response of the target response 18. Contrary to the minimum phase target response that arises from MMSE adaptation with a monic constraint, the simplest practical choice of the target response phase for recording channels may be a linear phase, which has advantages that no phase equalization may be required, i.e. the nominal equalizer needs only to handle amplitude channel distortions. This relaxes the requirements on the equalizer complexity.

A linear phase target avoids automatically the interaction problem that arises between the target adaptation and the timing recovery loop, and it allows simplifications of the Viterbi detector without loss in BER because the total number of branch metrics that need to be computed at every clock cycle is roughly halved. Complexity reduction can also be obtained by folding the Viterbi detector trellis. In addition, for a linear phase target only half of the total number of target taps needs to be adapted. This halves the target adaptation complexity and improves its tracking capabilities compared to a situation where all the target taps need to be adapted. For a symmetric target response of length N_{g}, the adaptation rule of equation (17) can be compounded as

$$∀ p , 0 \leq p \leq \frac{{N}_{g} - 1}{2} , {p}^{′} = {N}_{g} - 1 - p \qquad Eq . ( 18 )$$

Γ′ₚ^{(k)}=(eₖ₋ₚ+e_{k-p′})^{T}ε−δₑ^{T}(bₖ₋ₚ+b_{k-p′}+2(eₖ₋ₚ+e_{k-p′})) Eq (19)

gₚ^{(k+1)}=gₚ^{(k)}−η(e)Γ′ₚ^{(k)}Π_{{M(b+2e)-M(b)<4α}δₑ^{T}δ_{e}} Eq. (20)

g_{p′}^{(k+1}=gₚ^{(k+1)} Eq (21)

A similar adaptation rule can be derived for antisymmetric target responses. This boils down to replacing eₖ₋ₚ+e_{k-p′} and bₖ₋ₚ+b_{k-p′} in equation (19) with eₖ₋ₚ−e_{k-p′} and bₖ₋ₚ−b_{k-p′} respectively, and changing the equation (21) to g_{p′}^{(k+1)}=−gₚ^{(k+1)}.

A distinction can be made between different recording channels. For optical channels and perpendicular magnetic recording channels, the target is preferably constrained to be symmetric and its energy is fixed to 1. For longitudinal magnetic recording channels, the target is preferably constrained to be antisymmetric with unit energy.

The invention provides several advantages. The invention improves bit-error rates, allowing higher capacities for reading data in data storage systems or higher throughput and more reliability for wired or wireless transmission channels. The implementation complexity of the adaptation loop is very low. In its simplest form, a single enable signal indicates if a part of the data signal (with sign inversion based on the bit-error sequence) should be added to the equalizer taps or not. Furthermore, the adaptation method is applicable in many domains, with the largest performance gains achieved in worst-case situations.

In addition, convergence of the adaptation loops is improved by use of the invention. In conventional systems, the adaptation loop may be enabled only when the error signal is below a certain threshold. During a very large error, such as due to external disturbances or due to the unavoidable peaks in additive white Gaussian noise, the adaptation loop is disabled. However, in the initial case of a non-converged adaptation loop, the errors tend to be large causing frequent disabling of the adaptation loop. This results in a slow initial convergence of the adaptation loop in a conventional system. The invention improves convergence of the adaptation loops in this situation. During initial operation of a non-optimum equalizer, the SAM values are large, and the adaptation loops are consequently enabled. This results in a high initial bandwidth of the adaptation loops and fast convergence. In the converged state, the SAM values are small causing frequent disabling of the adaptation, resulting in a lower bandwidth and less gradient noise.

The invention can be used in magnetic and optical storage systems, but also in wired and wireless communication systems. The adaptation method can be used for temporal equalization but also for spatial equalization as in 2D storage and in multiple-input multiple-output systems. Furthermore, the technique is not limited to binary signals, but is equally well applicable to multi-level symbol transmission.

It is to be understood that any feature described in relation to one embodiment may also be used in other of the embodiments. Furthermore, equivalents and modifications not described above may also be employed without departing from the scope of the invention, which is defined in the accompanying claims.

1. A method for equalizer and/or target response adaptation in a receiver (20) for a transmission channel (12), a transmitted data sequence (b) being input to the transmission channel and a received data signal (r) being output from the transmission channel, the method comprising detecting data in the received signal, characterized in that method further comprises:
deriving an error sequence (e) representing potential errors in the data detection;
deriving a first value (19) representing the likelihood of an error in the data detection, the first value being based on the error sequence and the received signal; and
enabling and disabling adaptation of the equalizer (14) and/or the target response (18) depending on the first value being below or above a predefined threshold value (Tₕ).

2. The method of claim 1, characterized in that the receiver includes a Viterbi detector (16), and the first value is derived from the difference in total path metric between the best path and the second best path in the Viterbi detector.

3. The method of claim 1, characterized in that the receiver includes a symbol-by-symbol detector (32), and the first value is derived from the difference of the squared distances between the detector input and its closest symbol (b¹ₖ) found by the symbol-by-symbol detector, and the detector input and its second closest symbol (b²ₖ) found by the symbol-by-symbol detector.

4. The method of claim 1, characterized in that the threshold value (Tₕ) is derived from the error sequence (e).

5. The method of claim 2, characterized in that the threshold value (Tₕ) is proportional to the Euclidian weight of the error sequence.

6. The method of claim 3, characterized in that the threshold value (Tₕ) is proportional to the square of the error sequence.

7. The method of claim 1, characterized in that the adaptation of the equalizer and/or the target response comprises correlating the received signal with a second value (δₑ) derived from the error sequence (e).

8. The method of claim 7, characterized in that the second value (δₑ) is derived from the error sequence (e) and the expected target response (g) for the transmission channel.

9. The method of claim 1, characterized in that the adaptation of the equalizer comprises correlating the received signal with the error sequence (e).

10. The method of claim 1, characterized in that the adaptation of the equalizer and/or the target response comprises scaling by an adaptation constant (−η(e)) dependent on the error sequence (e).

11. The method of claim 10, characterized in that the adaptation constant (−η(e)) is dependent on the Hamming weight of the error sequence (e).

12. A receiver (20) for a transmission channel (12), a transmitted data sequence (b) being input to the transmission channel and a received data signal (r) being output from the transmission channel, the receiver comprising:
a linear equalizer (14) for receiving the received data signal and generating a reference signal (x);
an adaptation means (22) for adjusting the equalizer; and
a data detector (16, 32) for receiving the reference signal and detecting data in the received signal;
characterized in that the detector derives a first value (19) representing the likelihood of a decision error in the data detection, the first value being based on the received signal and an error sequence (e) representing potential errors in the data detection; and
means for enabling the adaptation means in dependence on the first value being below or above a predefined threshold value (Tₕ).

13. The receiver of claim 12, characterized in that the detector is a Viterbi detector and the first value is derived from the difference in total path metric between the best path and the second best path in the Viterbi detector.

14. The receiver of claim 12, characterized in that the detector is a symbol-by-symbol detector (32), and the first value is derived from the difference of the squared distances between the detector input and its closest symbol (b¹ₖ) found by the symbol-by-symbol detector, and the detector input and its second closest symbol (b²ₖ) found by the symbol-by-symbol detector.

15. The receiver of claim 12, further comprising:
a target response (18) for generating a reference signal (17);
an adaptation means (40) for adjusting the target response; and
means for enabling the adaptation means (40) in dependence on the first value (19) being below or above a predefined threshold value (Tₕ).

16. The receiver of claim 12, characterized in that the threshold value (Tₕ) is derived from the error sequence (e).

17. The receiver of claim 13, characterized in that the threshold value (Tₕ) is dependent on the Euclidian weight of the bit-error sequence.

18. The receiver of claim 14, characterized in that the threshold value (Tₕ) is proportional to the square of the error sequence.

19. The receiver of claim 12, characterized in that the adaptation means (22, 40) includes means for correlating with a second value (δₑ) derived from the error sequence (e).

20. The receiver of claim 19, characterized in that the second value (δₑ) is derived from the error sequence (e) and the expected target response (g) for the transmission channel.

21. The receiver of claim 12, characterized in that the adaptation means (22, 40) includes means for correlating with the error sequence (e).

22. The receiver of claim 12, characterized in that the adaptation means (22, 40) includes means for scaling by an adaptation constant (−η(e)) dependent on the error sequence (e).

23. The receiver of claim 22, characterized in that the adaptation constant (−η(e)) is dependent on the Hamming weight of the error sequence (e).
